(19) United States
(12) Patent Application Publication
(10) Pub. No.: US 2003/0189263 A1
(43) Pub. Date: Oct. 9, 2003

(54) Semiconductor module

(75) Inventors: Seiji Sawada, Hyogo (JP); Hiroyuki Nakao, Hyogo (JP); Tatsuji Kobayashi, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha; Mitsubishi Electric Engineering Company Limited

(21) Appl. No.: 10/245,686

(22) Filed: Sep. 18, 2002

(30) Foreign Application Priority Data
Apr. 9, 2002 (JP) 2002-106775(P)

(51) Int. Cl. H01L 23/29

(52) U.S. Cl. 257/788

(57) ABSTRACT

A semiconductor module is provided with a module substrate, a plurality of semiconductor chips formed on the module substrate, and a mold resin formed so as to integrally cover the plurality of semiconductor chips. Then, a plurality of trenches is formed on the main surface of the module substrate, so as to be parallel to one side forming the main surface, on the side on which the bare chips are formed. Thereby, a semiconductor module can be obtained wherein it is possible to restrict separation of the mold resin from the module substrate.

### BACKGROUND OF THE INVENTION

1. Field of the Invention

The present invention relates to a semiconductor module wherein an IC (Integration Circuit) is mounted to a semiconductor module substrate.

2. Description of the Background Art

FIG. 9 is a perspective view showing a condition wherein single chips sealed in a mold resin are secured to a module substrate in a semiconductor module according to a prior art.

As shown in FIG. 9, single chips 102, wherein bare chips are sealed in a mold resin, are mounted on a module substrate 101, thereby the semiconductor module according to the prior art is formed.

In the above described semiconductor module according to the prior art, lead frames are formed in order to be secured to module substrate 101 so that single chips 102 are mounted on module substrate 101 before which a long period of time was spent in the process of the formation of the lead frames.

Therefore, the resin molding process becomes inefficient when single chips 102, respectively, are mounted to module substrate 101 after single chips 102 are individually sealed in resin since a plurality of single chips 102 is considered to be mounted to module substrate 101 in the semiconductor module according to the prior art.

Therefore, the present inventors have conceived the idea wherein a plurality of bare chips is covered in a mold resin so as to be integrated onto one module substrate in order to make efficient the process of the sealing of a plurality of bare chips in resin and, in that case, the mold resin is formed so as to be mounted onto the main surface of the module substrate and, therefore, there is a risk that the module substrate and the mold resin may separate from one another. Then, a method, in any form, for the prevention of such a separation has not been invented.

### SUMMARY OF THE INVENTION

An object of the present invention is to provide a semiconductor module wherein it is possible to suppress the separation of a module substrate and a mold resin in the case that a plurality of bare chips mounted on one module substrate is integrally covered with the mold resin.

Furthermore, as described above, in the case that a plurality of bare chips are integrally covered with a mold resin, the ratio of the area of the surface of the mold resin to the area of the surface of the plurality of bare chips becomes small in comparison with the case wherein single chips, respectively, are covered with the mold resin. Therefore, the heat that is generated by the bare chips at the time of the utilization of the semiconductor module becomes difficult to be released from the surface of the mold resin so that the semiconductor module is utilized at a temperature higher than of the semiconductor module according to the prior art.

Another object of the present invention is to provide a semiconductor module wherein the heat generated by a plurality of bare chips can be efficiently released to the outside from a mold resin of the semiconductor module in the case that the plurality of bare chips is covered with the mold resin so as to be integrated onto one semiconductor module substrate.

A semiconductor module according to a first aspect of the present invention is provided with a module substrate wherein trenches or mesas are formed on the main surface, a plurality of bare chips mounted on the main surface of the module substrate and a mold resin that is formed so as to integrally cover the plurality of bare chips and so as to adhere to the trenches or to the mesas.

According to this configuration, the adhesive strength occurring between the surface of the mold resin and the surface of the module substrate can be made great when the mold resin and the module substrate are secured to each other and, therefore, the separation of the mold resin and the module substrate can be restricted.

In the semiconductor module according to the first aspect of the present invention, the trenches or the mesas may be provided so as to extend in a short side direction of the rectangular main surface forming the module substrate.

Though, in general, a great shift between the mold resin and the module substrate due to the difference in the thermal expansion coefficient between the mold resin and the module substrate occurs in the long side direction, rather than in the short side direction, of the main surface of the module substrate, according to the above described configuration the trenches or the mesas function effectively against stress caused by the shift in the long side direction between the mold resin and the module substrate and, therefore, the stress load applied to the plurality of bare chips, respectively, is reduced.

A semiconductor module according to a second aspect of the present invention is provided with a module substrate, a plurality of bare chips mounted on the main surface of the module substrate, and a mold resin formed so as to integrally cover the plurality of bare chips, wherein the module substrate has an engaging member that is secured to the main surface and that engages the mold resin so that the module substrate and mold resin are restricted from separating from each other.

According to this configuration, the separation of the mold resin and the module substrate can be more surely restricted than in a technique wherein the separation of the mold resin and the module substrate can be restricted by using the irregularity formed on the main surface of the module substrate.

In the semiconductor module according to the second aspect of the present invention, the engaging member may be provided so as to extend in the short side direction of the rectangle forming the main surface.

As described above, though, in general, a great shift between the mold resin and the module substrate due to the difference in the thermal expansion coefficient between the mold resin and the module substrate occurs in the long side direction, rather than in the short side direction, of the main surface of the module substrate, according to the above described configuration the engaging member function effectively against stress caused by the shift in the long side direction between the mold resin and the module substrate and, therefore, the stress load applied to the plurality of bare chips, respectively, is reduced.

A semiconductor module according to a third aspect of the present invention is provided with a module substrate, a plurality of bare chips mounted on the main surface of the module substrate, and a mold resin formed so as to integrally cover the plurality of bare chips, wherein the module substrate has a plurality of securing parts provided between the module substrate and the respective bare chips in order to secure the module substrate and the respective bare chips and so as to protrude from the main surface of the module substrate and having sizes no greater than the area of the respective bare chips on the main surface and wherein the mold resin is formed so as to become placed between the respective bare chips and the molded substrate around the respective securing parts.

According to the above described configuration, the separation of the mold resin and the module substrate can be more surely restricted than in a technique wherein the separation of the mold resin and the module substrate can be restricted by using the irregularity formed on the main surface of the module substrate.

A semiconductor module according to a fourth aspect of the present invention is provided with a module substrate, a plurality of bare chips mounted onto the main surface of the module substrate, and a mold resin formed so as to integrally cover the plurality of bare chips, wherein the mold resin is formed so as to extend to the main surface of the rear side.

According to this configuration, the separation of the mold resin and the module substrate can be more surely restricted than in the above described technique wherein the separation of the mold resin and the module substrate can be restricted by using the irregularity formed on the main surface of the module substrate.

A semiconductor module according to a fifth aspect of the present invention is formed of a module substrate, bare chips mounted on the main surface of the module substrate, and a mold resin formed so as to integrally cover the plurality of bare chips and having an irregularity on the surface.

According to this configuration, in the case that a plurality of bare chips are mounted on one semiconductor module substrate, the heat generated by the plurality of bare chips can be efficiently released to the outside by efficient utilization of the irregularity of the mold resin of the semiconductor module.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view for describing a semiconductor module of a first embodiment;

FIG. 2 is a cross sectional view for describing the semiconductor module of the first embodiment;

FIG. 3 is a perspective view for describing a semiconductor module of a second embodiment;

FIG. 4 is a perspective view for describing the semiconductor module of the second embodiment;

FIG. 5 is a cross sectional view for describing a semiconductor module of a third embodiment;

FIG. 6 is a cross sectional view for describing a semiconductor module of a fourth embodiment;

FIG. 7 is a perspective view for describing a semiconductor module of a fifth embodiment;

FIG. 8 is a perspective view for describing the semiconductor module of the fifth embodiment; and

FIG. 9 is a perspective view for describing a semiconductor module according to a prior art.

### DESCRIPTION OF THE PREFERRED EMBODIMENTS

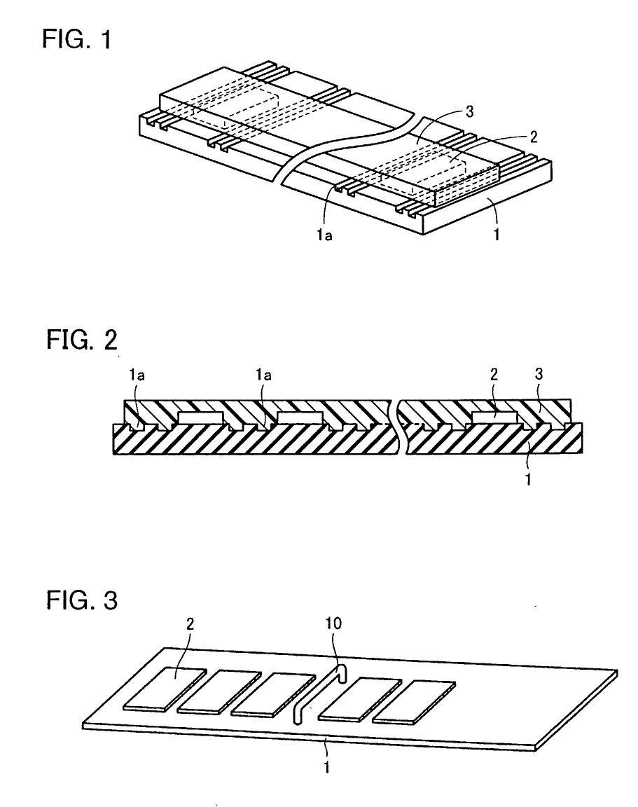

In the following, semiconductor modules according to the embodiments of the present invention will be described in reference to FIGS. 1 to 8.

(First Embodiment)

First, a semiconductor module of the first embodiment will be described in reference to FIGS. 1 and 2.

As shown in FIGS. 1 and 2, a semiconductor module of the first embodiment is provided with a module substrate 1, a plurality of bare chips 2 mounted on one of the main surfaces of this module substrate 1 and a mold resin 3 formed so as to integrally cover the plurality of bare chips 2.

In addition, trenches 1a are formed on portions other than the portions wherein the plurality of bare chips 2 are formed, that is to say, on regions other than the regions on the main surface wherein bare chips 2 and module substrate 1 contact each other, in the direction of one side of the quadrangular main surface that forms module substrate 1. Within these trenches 1a, mold resin 3 is filled in so as to be integrated with other parts.

Here, though the semiconductor module of the present embodiment has a configuration wherein trenches are provided in the main surface of module substrate 1, mesas may be formed on the main surface of module substrate 1 instead of forming trenches in the main surface of module substrate 1.

As described above, trenches la are provided in module substrates of the semiconductor module of the present embodiment and, therefore, mold resin 3 does not easily peel off from module substrate 1. That is to say, the degree of adhesion between mold resin 3 and module substrate 1 becomes great.

(Second Embodiment)

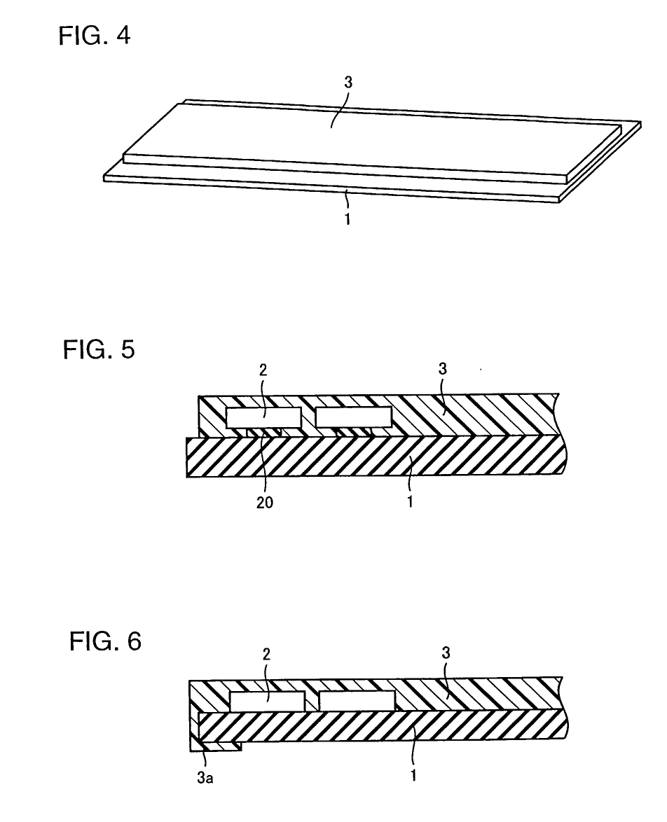

Next, a semiconductor module of the second embodiment will be described in reference to FIGS. 3 and 4.

As shown in FIGS. 3 and 4, the semiconductor module of the present embodiment is provided with a module substrate 1, a plurality of bare chips 2 formed on one of the main surfaces of module substrate 1, a mold resin 3 that integrally covers the plurality of bare chips 2 in a continuous manner, and an engaging member 10 formed between the plurality of bare chips 2. Engaging member 10 has two portions that are perpendicular to the main surface of module substrate 1 and a portion that is parallel to the main surface of module substrate 1 and connects these two perpendicular portions.

In addition, engaging member 10 is provided in the direction of one side of the quadrangular main surface forming module substrate 1 in a portion other than the portions wherein the plurality of bare chips 2 is formed on module substrate 1, that is to say, in a region other than the regions on the main surface wherein bare chips 2 and module substrate 1 contact each other.

Since such an engaging member 10 is provided, mold resin 3 fills in between engaging member 10 and module substrate 1, thereby module substrate 1 and mold resin 3 become difficult to separate after mold resin 3 hardens.

Here, FIG. 4 is a view showing the condition after mold resin 3 has been formed on module substrate 1 so as to integrally cover the plurality of bare chips 2, shown in FIG. 3.

(Third Embodiment)

Next, a semiconductor module of the third embodiment will be described in reference to FIG. 5.

The semiconductor module of the present embodiment is, as shown in FIG. 5, provided with a module substrate 1, a plurality of die pads 20 formed on the main surface of module substrate 1, a plurality of bare chips 2 formed on the respective die pads 20, and a mold resin 3 that integrally covers the main surface of module substrate 1, the respective surrounding areas of the plurality of die pads 20 and the respective bare chips 2. In addition, respective die pads 20 are formed so that the size thereof becomes smaller than the size of the main surfaces of the respective bare chips 2.

According to the above described configuration, mold resin 3 fills in between bare chips 2 and module substrate 1 since die pads 20 are smaller than the size of the main surfaces of bare chips 2. Thereby, separation-of mold resin 3 and module substrate 1 does not easily occur.

(Fourth Embodiment)

Next, a semiconductor module of the fourth embodiment will be described in reference to FIG. 6.

As shown in FIG. 6, the semiconductor module of the present embodiment is provided with a module substrate 1, a plurality of bare chips 2 formed on the main surface of module substrate 1, and a mold resin 3 that integrally covers the plurality of bare chips 2 in a continuous manner. In addition, mold resin 3 is not only formed on the surface of module substrate 1 on the side wherein bare chips 2 are formed but also has an extending portion 3a that integrally extends to a peripheral portion of the rear side main surface of module substrate 1.

As described above, an extending portion 3a of mold resin 3 that extends to the rear surface of module substrate 1 is formed and, therefore, separation of mold resin 3 and module substrate 1 does not easily occur.

(Fifth Embodiment)

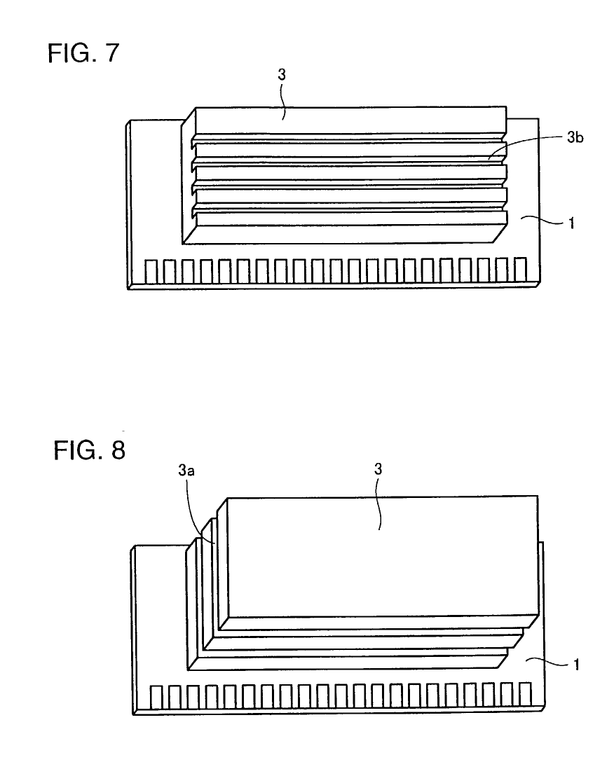

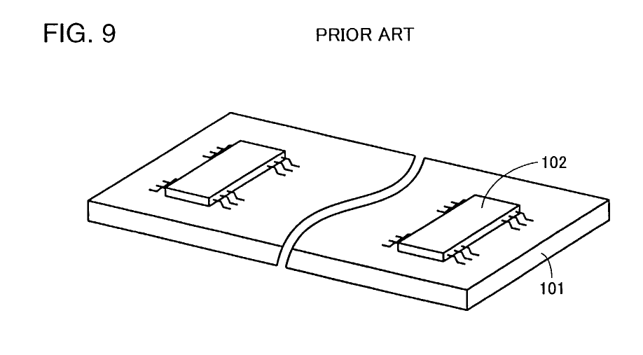

Next, a semiconductor module of the fifth embodiment will be described in reference to FIGS. 7 and 8.

As shown in FIGS. 7 and 8, a semiconductor module of the present embodiment is provided with a module substrate 1 and a mold resin 3 formed so as to integrally cover a plurality of bare chips formed on module substrate 1. In addition, trenches 3b for increasing the surface area are provided in the surface of mold resin 3. These trenches 3b may be formed in the direction of the long sides from among the sides forming the main surface, as shown in FIG. 7, in the main surface of mold resin 3 or may be formed in an encircling form surrounding the main surface of mold resin 3 in the sides of mold resin 3, as shown in FIG. 8.

According to the configuration described above, the surface area of mold resin 3 increases because trenches 3b are formed on the surface of mold resin 3 and, therefore, the heat generated by the plurality of bare chips at the time of the employment of the semiconductor module can be easily released to the outside from the surface of mold resin 3.

Here, the term “mesa” in the present specification is not used as a term that means a “mesa” having a portion that simply protrudes but, rather, is used as a term that means a “formation wherein a protruding portion forms a continuous line.”

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor module comprising:
a module substrate wherein a trench or a mesa is formed on a main surface;
a plurality of bare chips mounted on the main surface of the module substrate; and
a mold resin that integrally covers the plurality of bare chips and that is formed so as to be adhered to said trench or said mesa.

2. The semiconductor module according to claim 1, wherein said trench or said mesa is provided only in a region other than the region to which said plurality of bare chips is mounted on said main surface.

3. The semiconductor module according to claim 1, wherein
said trench or said mesa is provided so as to extend in a direction of short sides of the rectangular main surface forming said module substrate.

4. The semiconductor module, comprising:
a module substrate;
a plurality of bare chips mounted on a main surface of the module substrate; and
a mold resin formed so as to integrally cover the plurality of bare chips, wherein
said module substrate has an engaging member that is secured to said main surface and that engages said mold resin, thereby said module substrate and said mold resin are restricted from separating from each other.

5. The semiconductor module according to claim 4, wherein
said engaging member is provided in a region other than the region to which said plurality of bare chips is mounted on said main surface.

6. The semiconductor module according to claim 4, wherein
said engaging member is provided so as to extend in a direction of short sides of a rectangle forming said main surface.

7. A semiconductor module comprising:
a module substrate;
a plurality of bare chips mounted on a main surface of the module substrate; and
a mold resin formed so as to integrally cover the plurality of bare chips, wherein
said module substrate has a plurality of securing parts that is provided, in order to secure said plurality of bare chips to said module substrate, respectively, between the module substrate and said plurality of bare chips, that protrudes from the main surface of said module substrate and that has sizes no greater than the respective main surfaces of said plurality of bare chips.

8. A semiconductor module comprising:
a module substrate;
a plurality of bare chips mounted on a main surface of the module substrate; and
a mold resin formed so as to integrally cover the plurality of bare chips, wherein
said mold resin is formed so as to extend to a main surface of the rear side of said main surface.

9. The semiconductor module according to claim 8, wherein
said mold resin is formed so as to extend only to the vicinity of a peripheral portion of said main surface of the rear side.

10. A semiconductor module comprising:
a module substrate;
a plurality of bare chips mounted on a main surface of the module substrate; and
a mold resin formed so as to integrally cover the plurality of bare chips and having an irregularity on the main surface.

11. The semiconductor module according to claim 10, wherein
said irregularity is formed of trenches or mesas.

12. The semiconductor module according to claim 11, wherein
said trenches or said mesas are provided so as to extend in a direction of the long sides of the main surface of said mold resin.

13. The semiconductor module according to claim 11, wherein
said trenches or said mesas are provided on the sides of said mold resin in an encircling form surrounding the main surface of said mold resin.
